(19) United States
(12) Patent Application Publication
(10) Pub. No.: US 2016/0118453 A1
(43) Pub. Date: Apr. 28, 2016

(54) ORGANIC LIGHT-EMITTING DISPLAY APPARATUS

(71) Applicant: SAMSUNG DISPLAY CO., LTD., Yongin-City (KR)

(72) Inventor: Hyunduck CHO, Yongin-City (KR)

(21) Appl. No.: 14/672,461

(22) Filed: Mar. 30, 2015

(30) Foreign Application Priority Data
Oct. 27, 2014 (KR) 10-2014-0146424

(51) Int. Cl. H01L 27/32; F21V 3/04; F21V 13/02; H01L 51/52; F21V 11/00

(52) U.S. Cl. CPC H01L 27/3272; H01L 51/5218; F21V 11/00; F21V 13/02; F21V 3/049; F21V 3/0445

(57) ABSTRACT

An organic light-emitting display apparatus includes a display that includes an organic emission layer and a thin film transistor that drives the organic emission layer, and a backlight that irradiates light toward the thin film transistor.

### CROSS-REFERENCE TO RELATED APPLICATION

Korean Patent Application No. 10-2014-0146424, filed on Oct. 27, 2014, in the Korean Intellectual Property Office, and entitled: “Organic Light-Emitting Display Apparatus,” is incorporated by reference herein in its entirety.

### BACKGROUND

1. Field

Embodiments relate to an organic light-emitting display apparatus.

2. Description of the Related Art

Flat panel display apparatuses such as liquid crystal display apparatuses and organic light-emitting display apparatuses are suitable not only for being made compact to facilitate carrying electronic products but also for configuring large screens or high resolution screens.

An organic light-emitting display apparatus displays an image by using an organic light-emitting diode that emits lights by recombination of electrons and holes. The organic light-emitting display apparatus includes a plurality of pixels that are arranged in a matrix form over an area where scan lines and data lines intersect.

### SUMMARY

Embodiments are directed to an organic light-emitting display apparatus including a display including an organic emission layer and a thin film transistor that drives the organic emission layer, and a backlight that irradiates light toward the thin film transistor.

The backlight may irradiate light in at least one of an infrared range and an ultraviolet range.

The backlight may irradiate light having a wavelength in a range of from 100 nm to 380 nm.

The backlight may irradiate visible light.

The apparatus may further include a light-blocking layer between the organic emission layer and the backlight.

The light-blocking layer may be located such that the visible light irradiated by the backlight is blocked from penetrating the display.

The display may further include a pixel electrode at a lower portion of the organic emission layer, the pixel electrode being connected to the thin film transistor, and an opposite electrode on the organic emission layer, the opposite electrode facing the pixel electrode.

The pixel electrode may be positioned adjacently to a pixel electrode of an adjacent pixel such that the visible light irradiated by the backlight does not penetrate the display.

The pixel electrode may reflect light emitted from the organic emission layer upwardly and may reflect light emitted from the backlight downwardly in a direction of the thin film transistor.

The apparatus may further include a first light-blocking electrode between the pixel electrode and a pixel electrode of an adjacent pixel, the first light-blocking electrode being located such that the visible light irradiated by the backlight is blocked from penetrating the display.

The first light-blocking electrode may be located on a same layer as the pixel electrode.

The display may further include a substrate, an active layer including a source region, a drain region, and a channel region between the source region and the drain region on the substrate, a gate electrode overlapping at least a portion of the channel region of the active layer, a source electrode connected to the source region of the active layer, a drain electrode connecting the drain region of the active layer and the pixel electrode, and a second light-blocking electrode located below a space between the pixel electrode and a pixel electrode of an adjacent pixel, the second light blocking electrode being positioned such that the visible light irradiated by the backlight does not penetrate the display.

The second light-blocking electrode may be located on a same layer as the gate electrode or on a same layer as the source electrode and the drain electrode.

A size of the second light-blocking electrode may be equal to or greater than a size of the space between the pixel electrode and the pixel electrode of the adjacent pixel.

The display may be located on the backlight. The thin film transistor may be located between the backlight and the organic emission layer.

The backlight may include a light source unit that irradiates light, a reflection layer that reflects a light leakage portion of the light irradiated from the light source unit, and a diffusion layer that scatters the light irradiated from the light source unit and the light leakage portion reflected by the reflection layer.

The light source unit may be located at a side surface of the diffusion layer.

The apparatus may further include a light-guiding layer located on the diffusion layer, the light guiding layer guiding light scattered by the diffusion layer to travel in a direction of the thin film transistor.

The organic emission layer may include a low molecular organic material that emits light when a voltage is applied to both ends of the low molecular organic material. The organic emission layer may further include at least one of a hole transport layer and a hole injection layer at a lower portion of the organic emission layer, and at least one of an electron transport layer and an electron injection layer on the organic emission layer.

The organic emission layer may include a high molecular organic material that emits light when a voltage is applied to both ends of the high molecular organic material. The organic emission layer may further include a hole transport layer at a lower portion of the organic emission layer.

### BRIEF DESCRIPTION OF THE DRAWINGS

Features will become apparent to those of skill in the art by describing in detail exemplary embodiments with reference to the attached drawings in which:

FIG. 1 illustrates a cross-sectional view of an organic light-emitting display apparatus according to an embodiment;

FIG. 2 illustrates a cross-sectional view of a display of an organic light-emitting display apparatus according to an embodiment;

FIG. 3 illustrates a cross-sectional view of a backlight of an organic light-emitting display apparatus according to an embodiment;

FIG. 4 illustrates a cross-sectional view of a display of an organic light-emitting display apparatus according to another embodiment;

FIG. 5 illustrates a cross-sectional view of a display of an organic light-emitting display apparatus according to another embodiment;

FIG. 6 illustrates a cross-sectional view of a display of an organic light-emitting display apparatus according to another embodiment;

FIG. 7 illustrates a graph that shows current-transmitting properties of a driving thin film transistor according to one or more embodiments; and

FIG. 8 illustrates a graph that shows a current difference varying with a luminance of a driving thin film transistor according to one or more embodiments.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “between” two layers, it can be the only layer between the two layers, or one or more intervening layers may also be present. Like reference numerals refer to like elements throughout.

As used herein, the term “and/or” includes any and all combinations of one or more of the associated listed items. Expressions such as “at least one of,” when preceding a list of elements, modify the entire list of elements and do not modify the individual elements of the list.

While such terms as “first” and “second” may be used to describe various components, such components must not be limited to the above terms. The above terms are used only to distinguish one component from another.

As used herein, the singular forms “a,” “an,” and “the” are intended to include the plural forms as well, unless the context clearly indicates otherwise.

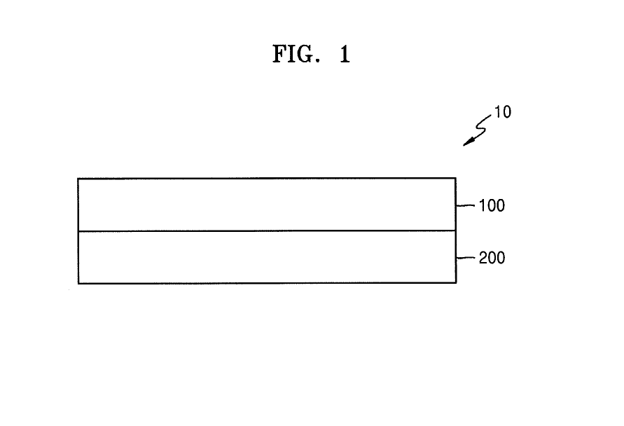

FIG. 1 illustrates a cross-sectional view of an organic light-emitting display apparatus 10 according to an embodiment.

Referring to FIG. 1, the organic light-emitting display apparatus 10 includes a display 100 and a backlight 200.

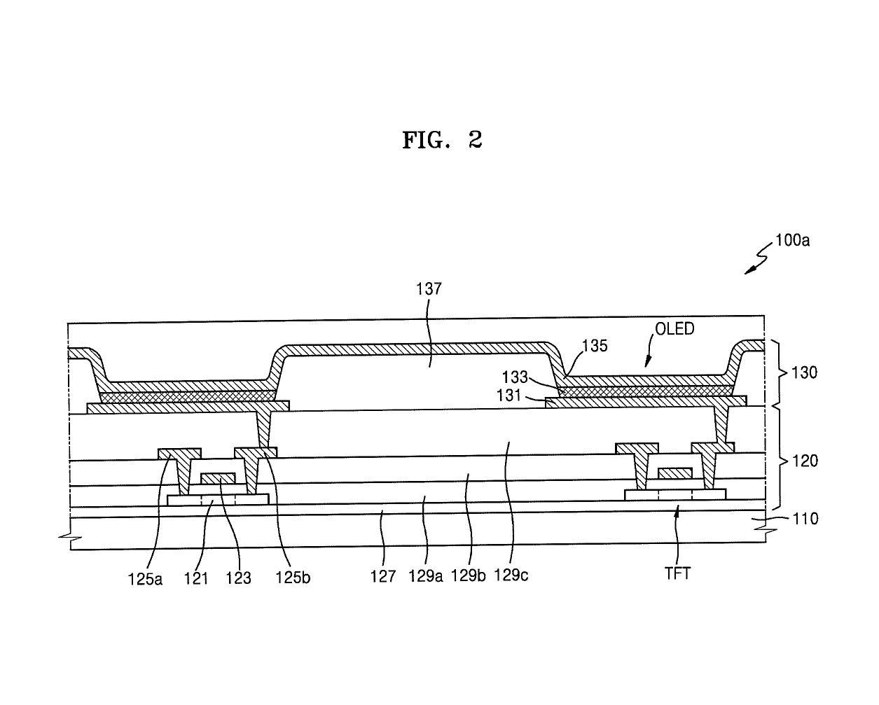

The display 100 may include an organic emission layer and a thin film transistor for driving the organic emission layer. The display 100 may further include a substrate on which the thin film transistor is formed and an organic light-emitting device connected to the thin film transistor and including the organic emission layer. As shown in FIG. 1, the display 100 may be disposed on the backlight 200. The display 100 included in the organic light-emitting display apparatus 10 will be described in detail below with reference to FIG. 2.

The backlight 200 may irradiate light toward the thin film transistor included in the display 100.

FIG. 2 illustrates a cross-sectional view of a display 100a of an organic light-emitting display apparatus according to an embodiment.

Referring to FIG. 2, the display 100a may include a substrate 110, an organic light-emitting device OLED, and a thin film transistor TFT array for driving the organic light-emitting device OLED.

The substrate 110 may be a rigid insulating substrate that is formed of a transparent glass material including, for example, silicon dioxide (SiO₂). In other implementations, the substrate 110 may be flexible a insulating substrate that is formed of a transparent plastic material. The organic light-emitting device OLED and a thin film transistor TFT may be disposed on the substrate 110.

The display 100a may include a plurality of pixels arranged in a matrix form. Each pixel may include the organic light-emitting device OLED, and an electronic device electrically connected to the organic light-emitting device OLED. The electronic device may include at least two thin film transistors TFT, including a driving thin film transistor and a switching thin film transistor, and a storage capacitor. The electronic device may be electrically connected to wires and may be driven by receiving an electrical signal from a driver circuit outside the display 100a. An arrangement of the electronic device electrically connected to the organic light-emitting device OLED and the wires is referred to as the thin film transistor TFT array.

The display 100a may include a device/wiring layer 120 including the thin film transistor TFT array, and an organic light-emitting device layer 130 including an organic light-emitting device OLED array.

The device/wiring layer 120 may include a driving thin film transistor TFT for driving the organic light-emitting device OLED, a switching thin film transistor, a capacitor, and wires connected to the thin film transistors or the capacitor.

A buffer layer 127 may be disposed on the substrate 110 to planarize an upper surface thereof and prevent the penetration of impurities. The buffer layer 127 may be formed of an inorganic insulating material.

An active layer 121 may be disposed on a predetermined region of an upper portion of the buffer layer 127. The active layer 121 may be formed by, for example, forming silicon, an inorganic semiconductor, an organic semiconductor, or the like on the entire surface of the substrate 110 on the buffer layer 127 and then patterning the same by using a photolithography process or an etching process. The inorganic semiconductor may be, for example, an oxide semiconductor. If the active layer 121 is formed of silicon, after an amorphous silicon layer may be formed on the entire surface of the substrate 110, the amorphous silicon layer may be crystallized to form a polycrystalline silicon layer, and the polycrystalline silicon layer may be patterned. Thereafter, surrounding regions may be doped with impurities, thereby forming the active layer 121 including a source region, a drain region, and a channel region between the source region and the drain region.

A gate insulating film 129a may be disposed on the active layer 121. A gate electrode 123 may be disposed on a predetermined area of an upper portion of the gate insulating film 129a. The gate electrode 123 may be connected to a gate line to which a control signal for controlling the thin film transistor TFT is applied. An interlayer insulating film 129b may be disposed on an upper portion of the gate electrode 123. The interlayer insulating film 129b may include a contact hole exposing a source region and a drain region of the active layer 121. A source electrode 125a and a drain electrode 125b may be electrically connected to the source region and the drain region of the active layer 121, respectively, via the contact hole of the interlayer insulating film 129b. The thin film transistor TFT may be protected by being covered with a passivation film 129c. The passivation film 129c may include an inorganic insulating film and/or an organic insulating film. For example, the passivation film 129c may be a complex stack of an inorganic insulating film and an organic insulating film.

The organic light-emitting device OLED may be disposed on an upper portion of the passivation film 129c.

The organic light-emitting device layer 130 may include a pixel electrode 131 formed on the passivation film 129c, an opposite electrode 135 facing the pixel electrode 131, and an intermediate layer 133 between the pixel electrode 131 and the opposite electrode 135.

If the organic light-emitting display apparatus 10 is of a top-emission type, the pixel electrode 131 may be a reflection electrode and the opposite electrode 135 may be a semi-transmission electrode.

The pixel electrode 131 may be a reflection electrode. The pixel electrode 131 may include a structure in which a reflection layer and a transparent or semitransparent electrode layer that has a high work function are stacked. The pixel electrode 131 may serve as an anode.

A pixel defining film 137 covering edges of the pixel electrode 131 and including a predetermined opening portion which exposes a central portion of the pixel electrode 131 may be disposed on the pixel electrode 131. The intermediate layer 133 including an organic emission layer that emits light may be disposed on a region limited by the opening portion. The region limited by the opening portion may be defined as an emission region, and a region in which the pixel defining film 137 is disposed may be defined as a non-emission region.

The opposite electrode 135 may be a transmission-type electrode. The opposite electrode 135 may be a semi-transmission film in which a metal having a low work function is thinly formed. In order to address high resistance of the thin metal semi-transmission film, a transparent conduction film formed of a transparent conductive oxide may be stacked on the metal semi-transmission film. The opposite electrode 135 may be formed in the form of a common electrode over the entire surface of the substrate 110 and may serve as a cathode. In another implementation, polarities of the pixel electrode 131 and the opposite electrode 135 may be reversed.

The intermediate layer 133 may include an organic emission layer. A low molecular organic material or a high molecular organic material may be used to form the organic emission layer. If the organic emission layer is a low molecular organic layer formed of a low molecular organic material, a hole transport layer (HTL) and a hole injection layer (HIL) may be disposed in a direction of the pixel electrode 131 with respect to the organic emission layer. An electron transport layer (ETL) and an electron injection layer (EIL) may be disposed in a direction of the opposite electrode 135 with respect to the organic emission layer. If the organic emission layer is a high molecular organic layer formed of a high molecular organic material, the HTL may be provided in a direction of the pixel electrode 131 with respect to the organic emission layer.

Although a structure in which the organic light-emitting device layer 130 is disposed on the device/wiring layer 120 in which the driving thin film transistor TFT is disposed is illustrated in the present drawings, the structure may have various modifications. For example, the structure of the display 100a may be a structure in which the pixel electrode 131 of the organic light-emitting device OLED is formed on the same layer as the active layer 121 of the thin film transistor TFT, a structure in which the pixel electrode 131 is formed on the same layer as the gate electrode 123 of the thin film transistor TFT, or a structure in which the pixel electrode 131 is formed on the same layer as the source electrode 125a and the drain electrode 125b.

Also, although it is illustrated in the present drawings that the gate electrode 123 of the driving thin film transistor TFT is disposed on the active layer 121, in other implementations, the gate electrode 123 may be disposed below the active layer 121.

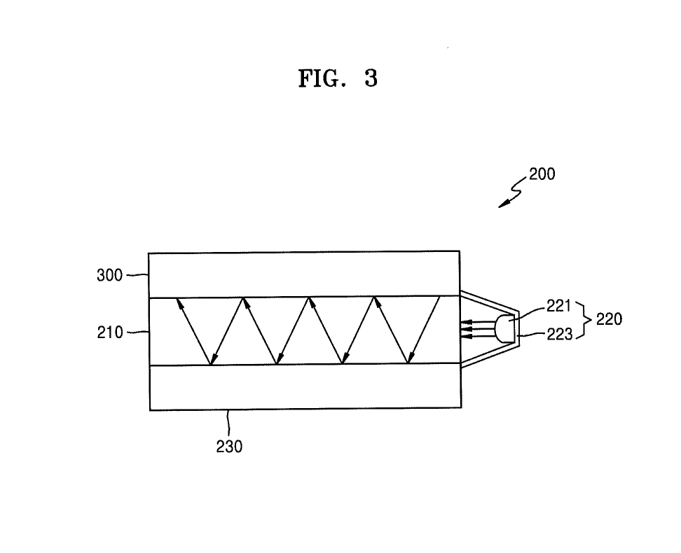

Hereinafter, the backlight 200 included in the organic light-emitting display apparatus 10 will be described in detail with reference to FIG. 3.

FIG. 3 illustrates a cross-sectional view of a backlight 200 of an organic light-emitting display apparatus according to an embodiment.

Referring to FIG. 3, the backlight 200 may include a diffusion layer 210, a light source unit 220, a reflection layer 230, and a light-guiding layer 300.

The diffusion layer 210 may evenly scatter light irradiated from the light source unit 220 and light reflected by the reflection layer 230, thereby increasing luminance of the backlight 200.

The diffusion layer 210 may be a polyethylene terephthalate (PET) resin, as an example. For example, the diffusion layer 210 may be a PET film on which a surface diffusion layer is coated.

The light source unit 220 may irradiate light toward the diffusion layer 210. As shown in FIG. 3, the light source unit 220 may be disposed at a side surface of the diffusion layer 210, as an example.

The light source unit 220 may include a lamp 221 and a lamp housing 223. In an implementation, the light source unit 220 may include a plurality of lamps 221 and a plurality of lamp housings 223 that are disposed in parallel.

The lamp 221 may irradiate light in at least one of the infrared range, ultraviolet range, and visible range. For example, the lamp 221 may irradiate light having a wavelength ranging from 100 nm to 380 nm.

The lamp 221 may be at least one of cold cathode fluorescent lamp (CCFL), external electrode fluorescent lamp (EEFL), and light emitting diode (LED), as examples.

The reflection layer 230 may reflect a light leakage portion of light irradiated from the light source unit 220.

The reflection layer 230 may be disposed on a lower portion of the diffusion layer 210. The reflection layer 230 may reflect a downward light leakage irradiated from the light source unit 220 to be directed back to the diffusion layer 210. The reflection layer 230 may also be formed on an interior wall of the lamp housing 223. The reflection layer 230 may reflect light irradiated from the lamp 221 such that the light is directed toward the diffusion layer 210.

The reflection layer 230 may be a white color series material having a high reflectivity, or a metal material such as silver (Ag) or aluminum (Al), as examples.

The backlight 200 may further include a light-guiding layer 300 that guides light scattered by the diffusion layer 210 to be directed in a direction of a thin film transistor TFT (refer to FIG. 2).

The light-guiding layer 300 may be disposed between the display 100a (refer to

FIG. 2) and the diffusion layer 210. For example, the light-guiding layer 300 may be on the diffusion layer 210. The light-guiding layer 300 may collect light scattered by the diffusion layer 210, thereby increasing luminance of the backlight 200.

The light-guiding layer 300 may be at least one of a glass and an optical sheet such as a prism sheet, as examples.

According to an embodiment, when the light source unit 220 shines invisible light such as infrared light or ultraviolet light on the thin film transistor TFT (refer to FIG. 2) of the display 100a (refer to FIG. 2), charges trapped in the channel region of an active layer 121 (refer to FIG. 2) may be de-trapped. As a result, an after-image of the display 100a (refer to FIG. 2) due to hysteresis properties of the thin film transistor TFT (refer to FIG. 2) may be removed.

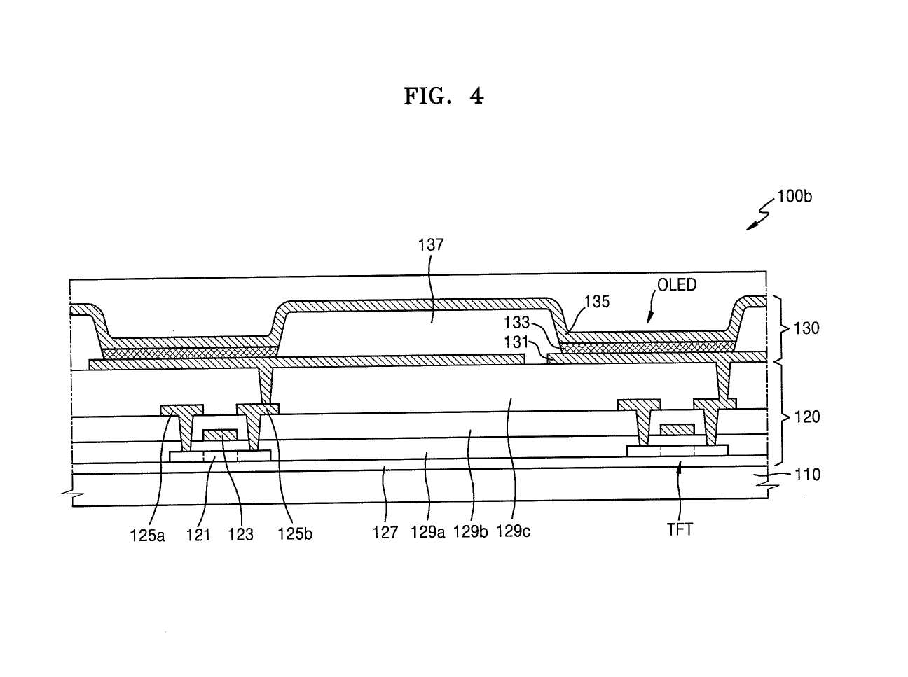

According to another embodiment, the light source unit 220 may also shine visible light on the thin film transistor TFT (refer to FIG. 2) of the display 100a (refer to FIG. 2). The display 100a (refer to FIG. 2) may include a light-blocking layer preventing visible light from penetrating the display 100a (refer to FIG. 2). Hereinafter, for simplification, a description of parts or components that are the same as those in FIG. 2 will not be repeated. The light-blocking layer will be described in detail with reference to FIGS. 4 through 6.

FIG. 4 illustrates a cross-sectional view of a display 100b of an organic light-emitting display apparatus according to another embodiment.

Referring to FIG. 4, pixel electrodes 131 of the display 100b may be disposed adjacent to each other such that visible light irradiated by a backlight 200 (refer to FIG. 3) does not penetrate the display 100b and reach a viewer.

A pixel electrode 131 included in an organic light-emitting device layer 130 may prevent visible light from penetrating the display 100b.

For example, the pixel electrode 131 may cover substantially the entire surface of a passivation film 129c. When an interval between the pixel electrodes 131 is small, the visible light irradiated by the backlight 200 (refer to FIG. 3) may be effectively blocked. The interval between the pixel electrodes 131 may be less than tens of micrometers. For example, the interval between the pixel electrodes 131 may be about 10 μm. For example, the interval between the pixel electrodes 131 may be about 4 μm. For example, the interval between the pixel electrodes 131 may be the same as a critical dimension, or may be several times a critical dimension.

The pixel electrode 131 may reflect light emitted from an organic emission layer upwardly and may reflect light emitted from the backlight 200 (refer to FIG. 3) downwardly in a direction of a thin film transistor TFT.

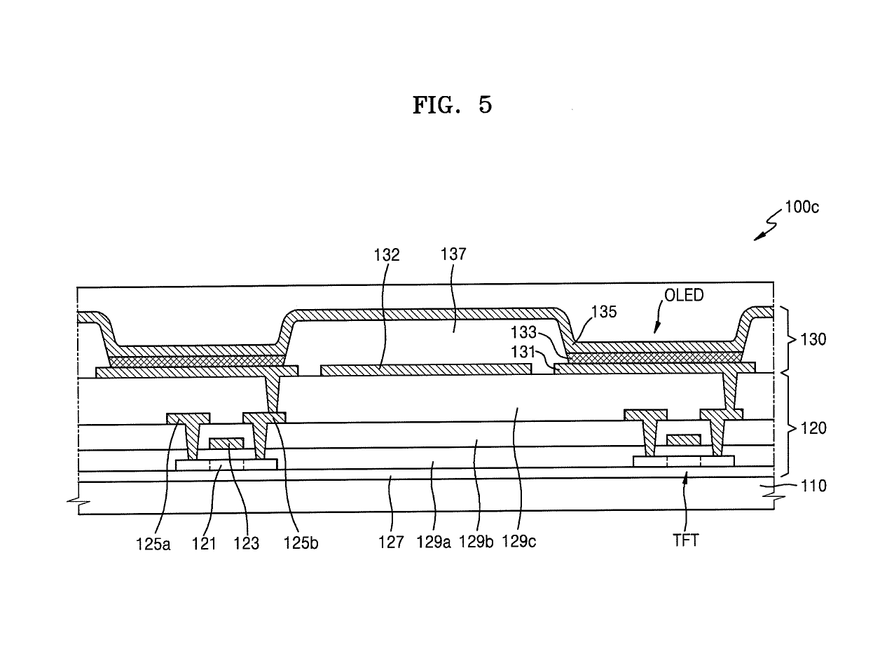

Referring to FIG. 5, a display 100c may include a first light-blocking electrode 132 disposed between pixel electrodes 131 such that visible light irradiated by a backlight 200 (refer to FIG. 3) does not penetrate the display 100c and reach a viewer.

The first light-blocking electrode 132 included in an organic light-emitting device layer 130 may prevent visible light from penetrating the display 100c.

For example, the first light-blocking electrode 132 may be disposed between the pixel electrodes 131 on the same layer as a pixel electrode 131. When an interval between the first light-blocking electrode 132 and the pixel electrode 131 is small, the visible light irradiated by the backlight 200 (refer to FIG. 3) may be effectively blocked. The interval between the first light-blocking electrode 132 and the pixel electrode 131 may be less than tens of micrometers. For example, the interval between the first light-blocking electrode 132 and the pixel electrode 131 may be about 10 μm or about 4 μm. For example, the interval between the first light-blocking electrode 132 and the pixel electrode 131 may be the same as a critical dimension, or may be several times a critical dimension.

The first light-blocking electrode 132 may reflect light emitted from an organic emission layer upwardly and may reflect light emitted from the backlight 200 (refer to FIG. 3) downwardly in a direction of a thin film transistor TFT.

Although it is illustrated in FIG. 5 that the first light-blocking electrode 132 is disposed on the same layer as the pixel electrode 131, the display 100c may further include a first light-blocking electrode formed as a separate layer in a passivation film 129c.

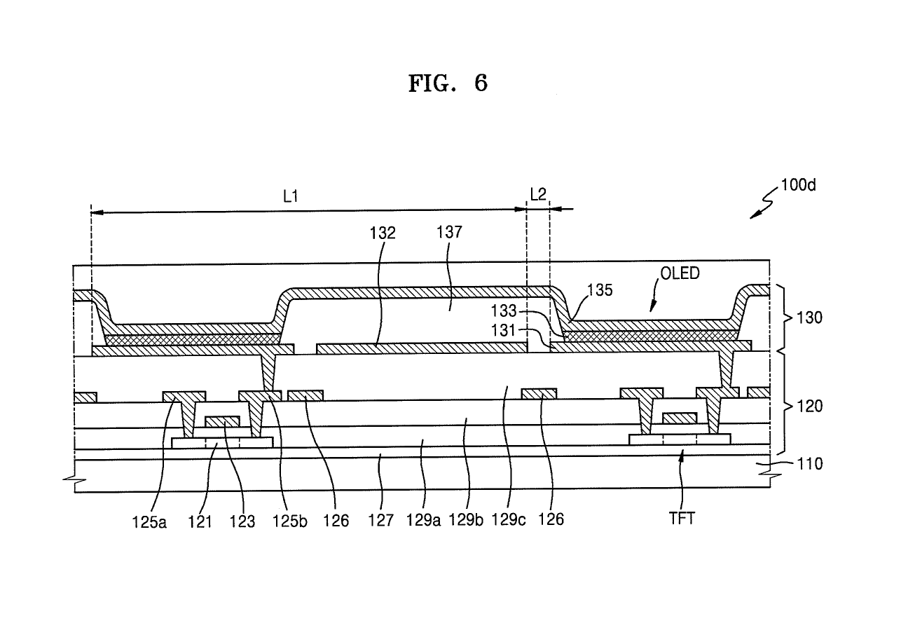

FIG. 6 illustrates a cross-sectional view of a display 100d of an organic light-emitting display apparatus according to another embodiment.

Referring to FIG. 6, a display 100d may further include a second light-blocking electrode 126 disposed such that visible light irradiated by a backlight 200 (refer to FIG. 3) does not penetrate the display 100d.

A first light-blocking electrode 132 included in an organic light-emitting device layer 130 and the second light-blocking electrode 126 included in a device/wiring layer 120 may prevent visible light from penetrating the display 100d.

For example, the second light-blocking electrode 126 may be disposed on the same layer as a source electrode 125a and a drain electrode 125b of a thin film transistor TFT. In other implementations, the second light-blocking electrode 126 may be disposed on the same layer as a gate electrode 123 of the thin film transistor TFT. The second light-blocking electrode 126 may be disposed below a space between a pixel electrode 131 and the first light-blocking electrode 132. A size (for example, a width) of the second light-blocking electrode 126 may be equal to or greater than an interval between the pixel electrode 131 and the first light-blocking electrode 132.

According to another embodiment, a pixel electrode 131 included in an organic light-emitting device layer 130 and a second light-blocking electrode 126 included in a device/wiring layer 120 may prevent visible light from penetrating a display 100. For example, the second light-blocking electrode 126 may be disposed below a space between pixel electrodes 131. A size of the second light-blocking electrode 126 may be equal to or greater than an interval between the pixel electrodes 131.

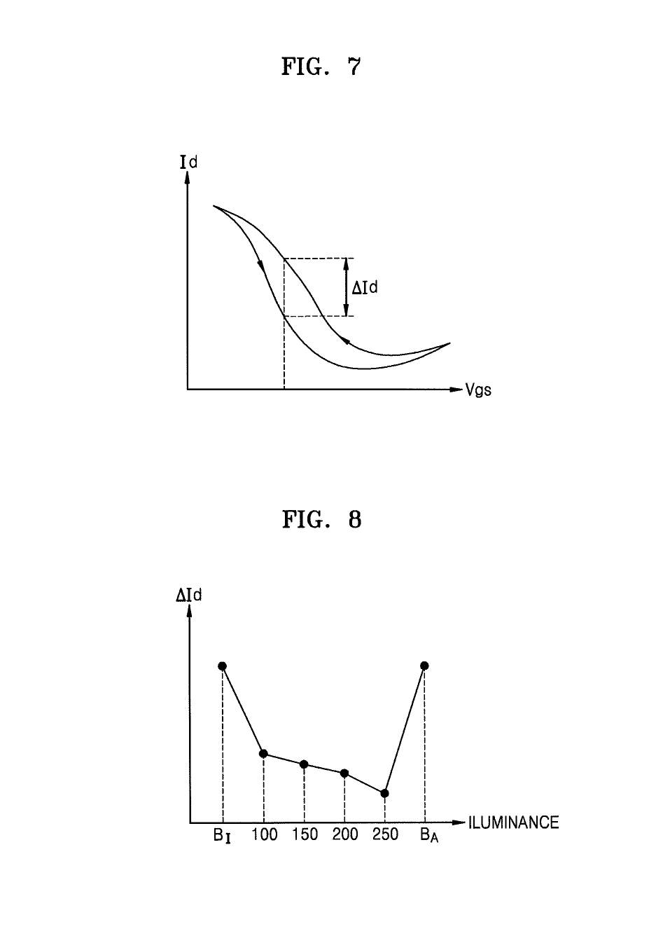

FIG. 7 illustrates a graph that shows current-transmitting properties of a driving thin film transistor according to one or more embodiments.

Referring to FIG. 7, a thin film transistor TFT (refer to FIG. 2) may have hysteresis properties in which a current Id curve when a gate voltage Vgs changes from a low voltage to a high voltage and the current Id curve when the gate voltage Vgs changes from a high voltage to a low voltage are different. Due to the hysteresis properties, a threshold voltage of the thin film transistor TFT (refer to FIG. 2) may fluctuate, thereby causing an after-image of an image. Hereinafter, an organic light-emitting display apparatus 10 according to one or more embodiments which has improved hysteresis properties will be described with reference to FIG. 8.

FIG. 8 illustrates a graph that shows a current difference depending on luminance of a driving thin film transistor according to one or more embodiments.

Referring to FIG. 8, a drain current difference ΔId of a thin film transistor TFT (refer to FIG. 2) measured when light is irradiated from a backlight 200 (refer to FIG. 3) onto the thin film transistor TFT (refer to FIG. 2) (when luminance is 100 ranges from 100 nit to 250 nit) is less than the drain current difference ΔId of the thin film transistor TFT (refer to FIG. 2) measured when light is not irradiated from the backlight 200 (refer to FIG. 3) (when luminance is B_{I} or B_{A}). In the case that light is irradiated from the backlight 200 (refer to FIG. 3), as luminance increases, the drain current difference ΔId of the thin film transistor TFT (refer to FIG. 2) decreases.

B_{I} denotes when the backlight 200 (refer to FIG. 3) has not yet irradiated light toward the thin film transistor TFT (refer to FIG. 2). B_{A} denotes when the backlight 200 (refer to FIG. 3) has finished irradiating light toward the thin film transistor TFT (refer to FIG. 2). That is, B_{I} and B_{A} denote states in which light is not irradiated onto the thin film transistor TFT (refer to FIG. 2).

The decrease in the drain current difference ΔId of the thin film transistor TFT (refer to FIG. 2) indicates an improvement of hysteresis properties. Without being bound to any theory, it is believed that in the case that the thin film transistor TFT (refer to FIG. 2) absorbs light, charges from a channel region of an active layer 121 (refer to FIG. 2) may be de-trapped, and thus hysteresis properties of the thin film transistor TFT (refer to FIG. 2) may be relieved, thereby improving an after-image caused by hysteresis properties.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. An organic light-emitting display apparatus, comprising:
a display including an organic emission layer and a thin film transistor that drives the organic emission layer; and
a backlight that irradiates light toward the thin film transistor.

2. The apparatus as claimed in claim 1, wherein the backlight irradiates light in at least one of an infrared range and an ultraviolet range.

3. The apparatus as claimed in claim 1, wherein the backlight irradiates light having a wavelength in a range of from 100 nm to 380 nm.

4. The apparatus as claimed in claim 1, wherein the backlight irradiates visible light.

5. The apparatus as claimed in claim 4, further comprising a light-blocking layer between the organic emission layer and the backlight.

6. The apparatus as claimed in claim 5, wherein the light-blocking layer is located such that the visible light irradiated by the backlight is blocked from penetrating the display.

7. The apparatus as claimed in claim 4, wherein the display further includes:
a pixel electrode at a lower portion of the organic emission layer, the pixel electrode being connected to the thin film transistor; and
an opposite electrode on the organic emission layer, the opposite electrode facing the pixel electrode.

8. The apparatus as claimed in claim 7, wherein the pixel electrode is located adjacently to a pixel electrode of an adjacent pixel such that the visible light irradiated by the backlight does not penetrate the display.

9. The apparatus as claimed in claim 7, wherein the pixel electrode reflects light emitted from the organic emission layer upwardly and reflects light emitted from the backlight downwardly in a direction of the thin film transistor.

10. The apparatus as claimed in claim 7, further comprising a first light-blocking electrode between the pixel electrode and a pixel electrode of an adjacent pixel, the first light-blocking electrode being located such that the visible light irradiated by the backlight is blocked from penetrating the display.

11. The apparatus as claimed in claim 10, wherein the first light-blocking electrode is located on a same layer as the pixel electrode.

12. The apparatus as claimed in claim 7, wherein the display further comprises:
a substrate;
an active layer including a source region, a drain region, and a channel region between the source region and the drain region on the substrate;
a gate electrode overlapping at least a portion of the channel region of the active layer;
a source electrode connected to the source region of the active layer;
a drain electrode connecting the drain region of the active layer and the pixel electrode; and
a second light-blocking electrode located below a space between the pixel electrode and a pixel electrode of an adjacent pixel, the second light blocking electrode being positioned such that the visible light irradiated by the backlight does not penetrate the display.

13. The apparatus as claimed in claim 12, wherein the second light-blocking electrode is located on a same layer as the gate electrode or on a same layer as the source electrode and the drain electrode.

14. The apparatus as claimed in claim 12, wherein a size of the second light-blocking electrode is equal to or greater than a size of the space between the pixel electrode and the pixel electrode of the adjacent pixel.

15. The apparatus as claimed in claim 1, wherein:
the display is located on the backlight, and
the thin film transistor is located between the backlight and the organic emission layer.

16. The apparatus as claimed in claim 1, wherein the backlight includes:
a light source unit that irradiates light;
a reflection layer that reflects a light leakage portion of the light irradiated from the light source unit; and
a diffusion layer that scatters the light irradiated from the light source unit and the light leakage portion reflected by the reflection layer.

17. The apparatus as claimed in claim 16, wherein the light source unit is located at a side surface of the diffusion layer.

18. The apparatus as claimed in claim 16, further comprising a light-guiding layer located on the diffusion layer, the light guiding layer guiding light scattered by the diffusion layer to travel in a direction of the thin film transistor.

19. The apparatus as claimed in claim 1, wherein the organic emission layer includes a low molecular organic material that emits light when a voltage is applied to both ends of the low molecular organic material, and further includes at least one of a hole transport layer and a hole injection layer at a lower portion of the organic emission layer, and at least one of an electron transport layer and an electron injection layer on the organic emission layer.

20. The apparatus as claimed in claim 1, wherein the organic emission layer includes a high molecular organic material that emits light when a voltage is applied to both ends of the high molecular organic material and further includes a hole transport layer at a lower portion of the organic emission layer.
